(19) United States
(12) Patent Application Publication
(10) Pub. No.: US 2017/0088367 A1
(43) Pub. Date: Mar. 30, 2017

(54) TRANSFER APPARATUS

(71) Applicant: DAIHEN Corporation, Osaka (JP)

(72) Inventors: Sayako TAKARABE, Osaka-shi (JP); Jun IURA, Osaka-shi (JP)

(73) Assignee: DAIHEN Corporation, Osaka (JP)

(21) Appl. No.: 15/279,640

(22) Filed: Sep. 29, 2016

Related U.S. Application Data
(60) Provisional application No. 62/234,891, filed on Sep. 30, 2015.

(51) Int. Cl. B65G 49/06; B25J 18/04; H01L 21/677; B25J 5/02

(52) U.S. Cl. CPC B65G 49/067; B25J 5/02; B25J 18/04; H01L 21/67742; H01L 21/67745; Y10S 901/25

(57) ABSTRACT

A transfer apparatus capable of suppressing dust generation and reducing the manufacturing cost thereof is provided.

In a transfer apparatus including a transfer unit which moves on a rail to transfer an object and an arm mechanism which transmits the power from a drive source to the transfer unit, the arm mechanism includes a rotatable driving arm with one end thereof connected to the drive source, a driven arm with one end thereof connected to the transfer unit, and a gear mechanism which connects the other end of the driven arm to the other end of the driving arm and transmits the rotation of the driving arm to the driven arm.

### CROSS-REFERENCE TO RELATED APPLICATIONS

This Nonprovisional application claims priority under 35 U.S.C. §119(a) on Patent Application No. 62/234,891 filed in U.S. on Sep. 30, 2015, the entire contents of which are hereby incorporated by reference.

### FIELD

The present technology relates to a transfer apparatus that transfers an object.

### BACKGROUND AND SUMMARY

A vacuum transfer robot of a belt slidable type with the use of a belt mechanism and a guide is disclosed already in the past. A vacuum transfer robot of an arm slidable type is also disclosed.

In the vacuum transfer robot of a belt slidable type with the use of a belt mechanism and a guide, a belt is exposed to a vacuum region, and dust (particles) generated from the belt harms the clean environment.

The vacuum transfer robot of an arm slidable type comprises a large first arm having a hollow structure capable of housing a motor and a speed reducer, and a second arm connected to the first arm and a sliding member. The first arm has a complicated structure, which increases the manufacturing cost thereof.

The present disclosure has been made in view of the circumstances described above, and aims to provide a transfer apparatus capable of suppressing dust generation and reducing the manufacturing cost.

A transfer apparatus according to an aspect of the present disclosure comprises a transfer unit that moves on a rail to transfer an object and an arm mechanism that transmits power from a drive source to the transfer unit, and the arm mechanism comprises a rotatable driving arm with one end thereof connected to the drive source, a driven arm with one end thereof connected to the transfer unit, and a gear mechanism that connects the other end of the driven arm to the other end of the driving arm and that transmits rotation of the driving arm to the driven arm.

According to an aspect of the present disclosure, the driving arm is connected to the driven arm via the gear mechanism, which suppresses dust generation compared to the case of using a belt.

Moreover, one end of the driving arm is connected to the drive source while the driving arm houses no motor therein, which eliminates the need for the driving arm to have a hollow structure, and thereby simplifies the structure of the driving arm.

In the transfer apparatus according to an aspect of the present disclosure, the gear mechanism includes a first gear connected to the other end of the driving arm, and a second gear engaged with the first gear and connected to the other end of the driven arm.

According to an aspect of the present disclosure, the driving arm and the driven arm are connected to the first gear and the second gear, respectively, to smoothly transfer power from the drive source to the transfer unit.

In the transfer apparatus according to an aspect of the present disclosure, the first gear includes a first gear part and a first shaft part protruding from the first gear part, and the second gear includes a second gear part engaged with the first gear, and a second shaft part protruding from the second gear part in the direction opposite to the first shaft part. The driving arm is connected to the first shaft part whereas the driven arm is connected to the second shaft part.

According to an aspect of the present disclosure, the first shaft part and the second shaft part protrude in directions opposite from each other, while the driving arm and the driven arm are connected to the first shaft part and the second shaft part. Even if the driving arm and the driven arm rotate, they do not interfere with each other. If the driving arm and the driven arm interfere with each other, the movable range of the arm mechanism is limited to an area in which they do not interfere with each other. Since the driving arm and the driven arm do not interfere with each other, the movable range of the arm mechanism is longer compared to the case where they interfere with each other, and the length of the arm mechanism, i.e. the lengths of the driving and driven arms, may be made shorter with respect to the movable range of the arm mechanism in the longitudinal direction of a rail.

In the transfer apparatus according to an aspect of the present disclosure, the drive source is located next to a middle part in the longitudinal direction of the rail.

According to an aspect of the present disclosure, one end (base end) of the driving arm is connected to the drive source, and is positioned at a middle part in the longitudinal direction of the rail. If the arm mechanism is so configured as to move along a length corresponding to substantially half the length of the rail, the arm mechanism may move between both ends of the rail starting from a point at the middle part of the rail.

The above and further objects and features will more fully be apparent from the following detailed description with accompanying drawings.

### BRIEF DESCRIPTION OF THE DRAWINGS

FIG. 1 is a plan view schematically illustrating a transfer apparatus;

FIG. 2 is a perspective view schematically illustrating a transfer apparatus;

FIG. 3 is a section view schematically illustrating a transfer apparatus;

FIG. 4 is a plan view schematically illustrating a first arm mechanism;

FIG. 5 is a plan view schematically illustrating a gear mechanism;

FIG. 6 is a side section view schematically illustrating a gear mechanism; and

FIG. 7 is a plan view schematically illustrating a second arm mechanism.

### DETAILED DESCRIPTION OF NON-LIMITING EXAMPLE EMBODIMENTS

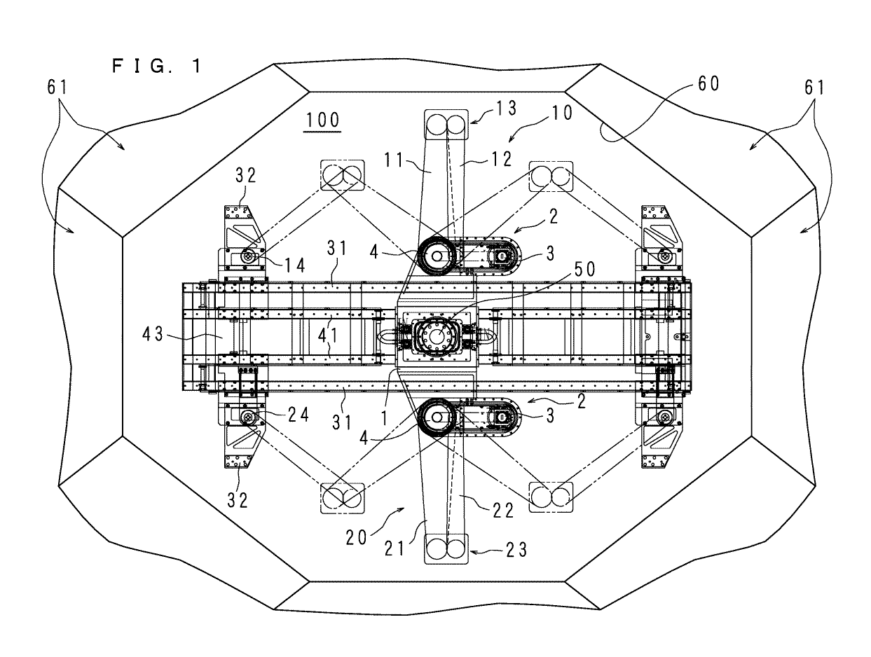

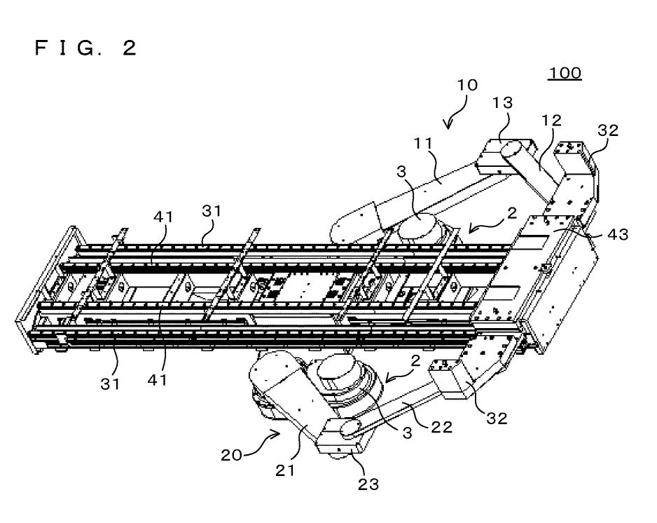

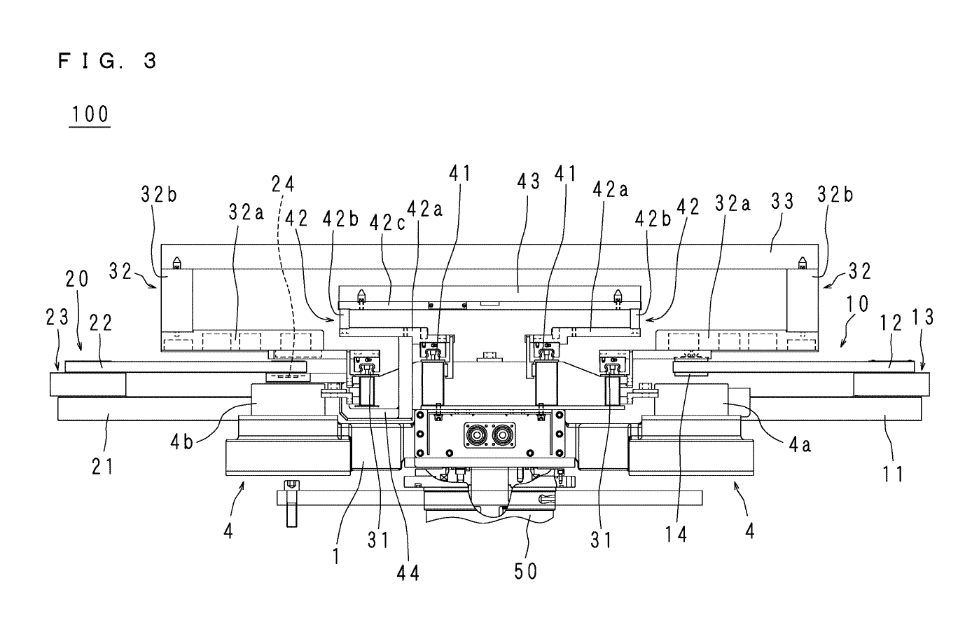

A transfer apparatus 100 according to an embodiment thereof will be described below with reference to the drawings. FIG. 1 is a plan view schematically illustrating the transfer apparatus 100, FIG. 2 is a perspective view schematically illustrating the transfer apparatus 100, and FIG. 3 is a section view schematically illustrating the transfer apparatus 100. In FIG. 1, the long-dashed double-short-dashed lines indicate a first arm mechanism 10 and a second arm mechanism 20 moved from the middle in the horizontal direction in FIG. 1 to the right or left side. A first hand holding member 33 which will be described later is not illustrated in FIGS. 1 and 2.

As illustrated in FIGS. 1 and 2, the transfer apparatus 100 has a laterally-long shape extending in the horizontal direction, and is housed in a housing 60 of a polygonal shape in plan view. Each wall surface of the housing 60 constitutes each wall surface of multiple chambers 61. A substrate processing device (not illustrated) is disposed in a predetermined chamber 61. On a wall surface of the housing 60, an opening (not illustrated) and a door (not illustrated) that opens/closes the opening are provided. The transfer apparatus 100 is supported by a support shaft 50 which protrudes upward from the floor and is rotatable about its axis. A substrate is transferred by the transfer apparatus 100 as described below, for example. The rotation of the support shaft 50 positions one end of the transfer apparatus 100 in front of the door of any one of the chambers 61. The substrate processing device is disposed in the chamber 61. The door of the chamber 61 opens, and the transfer apparatus 100 takes out the substrate which has been processed in the substrate processing device from the chamber 61. The support shaft 50 rotates, and the other end of the transfer apparatus 100 is positioned in front of the door of a different one of the chambers 61. This different one of the chambers 61 then opens, and the transfer apparatus 100 transfers the substrate to the different chamber 61.

As illustrated in FIG. 3, the transfer apparatus 100 has a support frame 1 which is connected to the upper end of the support shaft 50. As illustrated in FIG. 1, two first guide rails 31, 31 extending in the horizontal direction and two second guide rails 41, 41 being in parallel with the first guide rails 31, 31 are supported by the support frame 1. Two second guide rails 41, 41 are arranged between the two first guide rails 31 and 31. The first guide rail 31 and the second guide rail 41 have substantially the same length, and the ends of the first guide rail 31 are located at substantially the same positions as the ends of the second guide rail 41.

Each of the two first guide rails 31, 31 is provided with a first slider 32 which is slidable thereon. The first slider 32 includes a sliding element 32a and a protruding part 32b. The sliding element 32a protrudes from the first guide rail 31 to the side opposite to the second guide rail 41 and slides on the first guide rail. The protruding part 32b protrudes upward from a protruding end of the sliding element 32a. A first hand holding member 33 bridges over two protruding parts 32b and 32b. The first slider 32 and the first hand holding member 33 constitute a transfer unit.

Each of the two second guide rails 41, 41 is provided with a second slider 42 which is slidable thereon. The second slider 42 includes a sliding element 42a, a protruding part 42b, and an upper member 42c. The sliding element 42a protrudes from the second guide rail 41 to the first guide rail 31 side, and slides on the second guide rail 41. The protruding part 42b protrudes upward from a protruding end of the sliding element 42a. The upper member 42c is located above the protruding part 42b and bridges over two protruding parts 42b and 42b. The second hand holding member 43 is located over the upper member 42c. The second slider 42 and the second hand holding member 43 constitute a transfer unit.

The second slider 42 and the second hand holding member 43 are disposed below the first hand holding member 33 and between two protruding parts 32b and 32b without any interference. That is, the first slider 32 and the first hand holding member 33 slide on the first guide rail 31 whereas the second slider 42 and the second hand holding member 43 slide on the second guide rail 41, while not interfering with each other.

As illustrated in FIG. 1, two drive sources 2, 2 are supported by the support frame 1. Two drive sources 2, 2 are arranged adjacent to the middle parts in the longitudinal direction of the two first guide rails 31, 31, respectively. In plan view, in the direction perpendicular to the first guide rail 31, the drive source 2 is disposed near the first guide rail 31 at the side opposite from the second guide rail 41.

The drive source 2 includes a motor 3 and a speed reducer 4 connected to the motor 3 via a transmission member. In plan view, in the direction perpendicular to the first guide rail 31, the two speed reducers 4, 4 are positioned at the respective ends of the support frame 1. In the longitudinal direction of the first guide rail 31, the speed reducer 4 is positioned at substantially the middle of the first guide rail 31 and the second guide rail 41.

As illustrated in FIG. 3, an output shaft 4a of one speed reducer 4 protrudes upward from the support frame 1. A vacuum seal member is provided around the output shaft 4a to seal a gap between the output shaft 4a and the support frame 1. A first arm mechanism 10, which will be described later, is connected to the output shaft 4a. In the longitudinal direction of the first guide rail 31, the output shaft 4a is disposed at a position corresponding to the middle of the first guide rail 31.

An output shaft 4b of the other speed reducer 4 also protrudes upward from the support frame 1. A vacuum seal member is provided around the output shaft 4b to seal a gap between the output shaft 4b and the support frame 1. A second arm mechanism 20, which will be described later, is connected to the output shaft 4b. In the longitudinal direction of the second guide rail 41, the output shaft 4b is disposed at a position corresponding to the middle of the second guide rail 41.

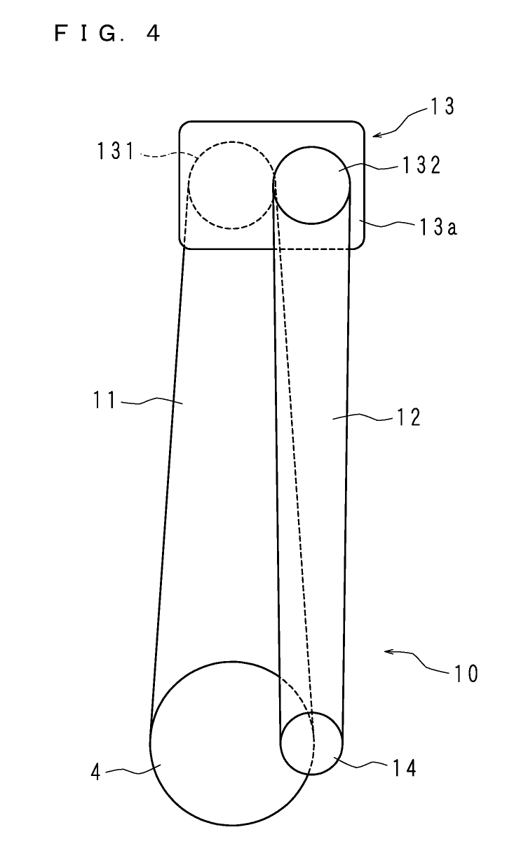

FIG. 4 is a plan view schematically illustrating the first arm mechanism 10. The first arm mechanism 10 is connected to the output shaft 4a. The first arm mechanism 10 includes a driving arm 11 connected to the speed reducer 4, a driven arm 12, and a gear mechanism 13 which connects the driven arm 12 to the driving arm 11.

One end (i.e. base end) of the driving arm 11 is connected to the output shaft 4a. One end of the driven arm 12 is connected to the sliding element 32a of the first slider 32 via a bearing 14. The other end of the driving arm 11 is connected to the other end of the driven arm 12 via the gear mechanism 13.

The driving arm 11 and the driven arm 12 are located at different positions in the axial direction of the output shaft 4a, i.e. vertical direction. According to the present embodiment, the driving arm 11 is positioned below the driven arm 12. It is noted that the driving arm 11 may also be located above the driven arm 12.

The first arm mechanism 10 is so configured to be able to move along the length corresponding to at least substantially half the length of the first guide rail 31. As described above, the base end of the driving arm 11 is connected to the output shaft 4a, and the output shaft 4a is disposed at a position corresponding to the middle of the first guide rail 31. Accordingly, the first arm mechanism 10 may move between the middle part of the first guide rail 31 and each end of the first guide rail 31. In other words, the first arm mechanism 10 is able to move along the entire length of the first guide rail 31.

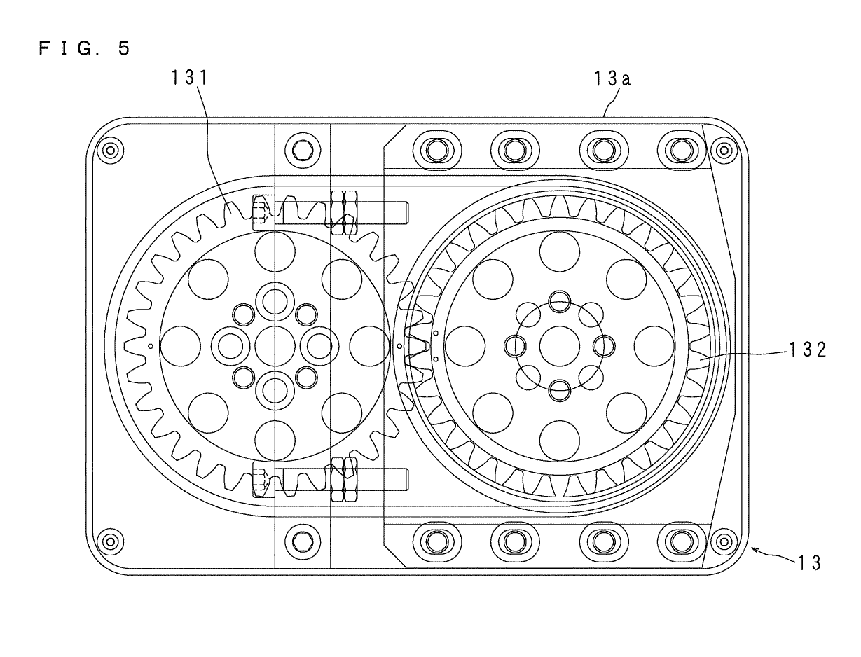

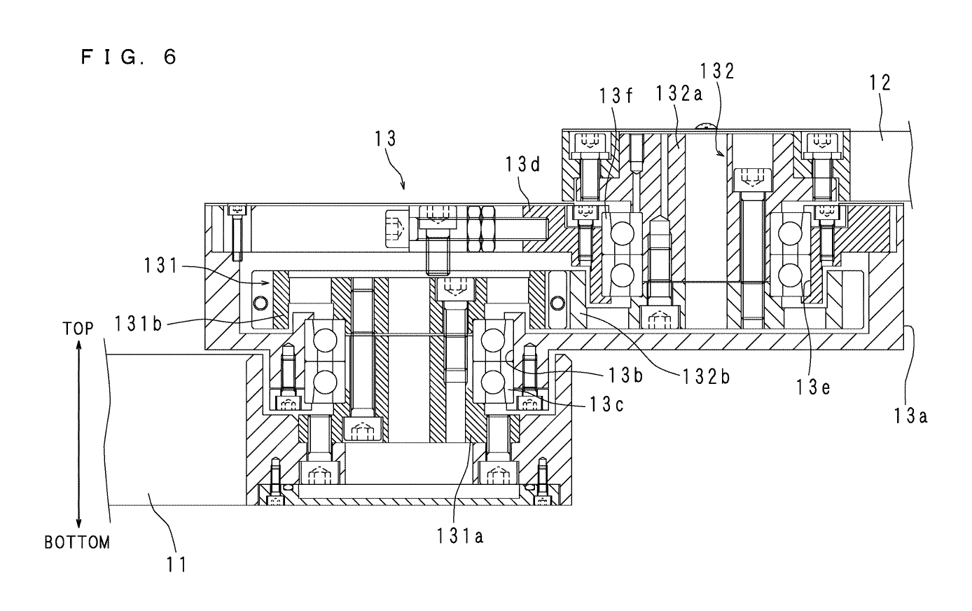

FIG. 5 is a plan view schematically illustrating the gear mechanism 13, and FIG. 6 is a side section view schematically illustrating the gear mechanism 13. The gear mechanism 13 includes a gear box 13a, a first gear 131 housed in the gear box 13a, and a second gear 132 also housed in the gear box 13a and engaged with the first gear 131. The gear box 13a is formed in a rectangular shape in plan view extending in a direction parallel to the first guide rail 31, and has an opened upper face. A first through hole 13b penetrating vertically is formed at the bottom face of one end of the gear box 13a. A first bearing 13c is coaxially fitted into the first through hole 13b. The first bearing 13c is, for example, a combination angular bearing.

The first bearing 13c supports the first gear 131. The first gear 131 includes a first shaft part 131a and a first gear part 131b. The first shaft part 131a is supported by the first bearing 13c, and extends vertically. The first gear part 131b is provided at the upper end of the first shaft part 131a. The first gear part 131b is disposed in the gear box 13a. The lower end of the first shaft part 131a protrudes to the lower side of the gear box 13a. The other end of the driving arm 11 is connected to the lower end of the first shaft part 131a.

A lid 13d is provided at the opening of the upper face of the gear box 13a, and a second through hole 13e penetrating vertically is formed in the lid 13d. In the longitudinal direction of the gear box 13a, the second through hole 13e is formed at the opposite side of the first through hole 13b. A second bearing 13f is coaxially fitted into the second through hole 13e. The second bearing 13f is, for example, a combination angular bearing.

The second bearing 13f supports the second gear 132. The second gear 132 includes a second shaft part 132a and a second gear part 132b. The second shaft part 132a is supported by the second bearing 13f, and extends vertically. The second gear part 132b is provided at the lower end of the second shaft part 132a. The second gear part 132b is disposed in the gear box 13a, and is engaged with the first gear part 131b. The upper end of the second shaft part 132a protrudes to the upper side of the lid 13d. The other end of the driven arm 12 is connected to the upper end of the second shaft part 132a.

In the case where the output shaft 4a rotates about the axis, the driving arm 11 rotates with its one end being the rotation center, and the gear mechanism 13 also rotates with the one end of the driving arm 11 being the rotation center. Since the other end of the driving arm 11 is connected to the first gear 131, the first gear 131 rotates about its axis and the second gear 132 also rotates. The rotation of the second gear 132 makes the driven arm 12 rotate with its other end being the rotation center, and the first slider 32 as well as the first hand holding member 33 that are connected to one end of the driven arm 12 move on the first guide rail 31 (see FIGS. 1 to 3). The first arm mechanism 10 is elongated and shortened in the horizontal direction.

As illustrated in FIG. 3, the output shaft 4b of the other speed reducer 4 protrudes upward from the support frame 1. A vacuum seal member is provided around the output shaft 4b to seal a gap between the output shaft 4b and the support frame 1. A second arm mechanism 20 is connected to the output shaft 4b.

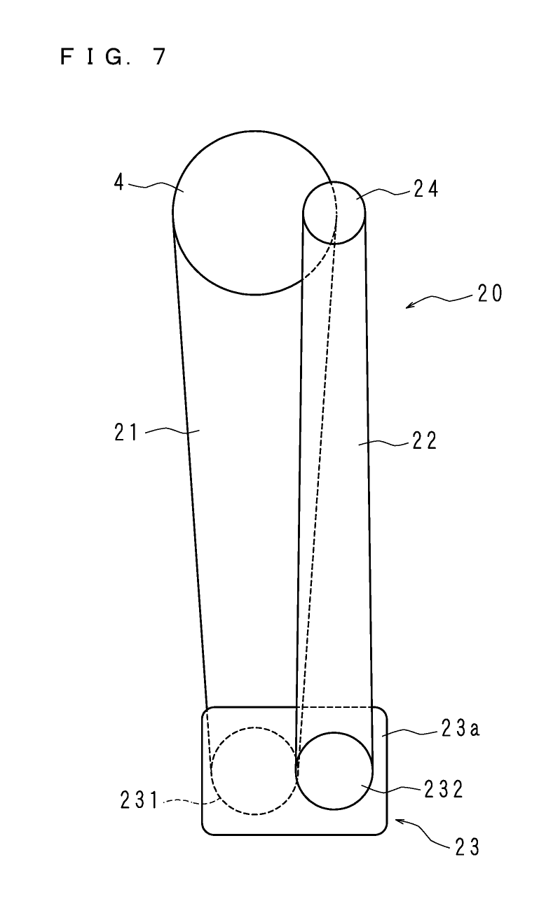

FIG. 7 is a plan view schematically illustrating the second arm mechanism 20. As in the first arm mechanism 10, the second arm mechanism 20 includes a driving arm 21 connected to the speed reducer 4, a driven arm 22, and a gear mechanism 23 which connects the driven arm 22 to the driving arm 21. Hereinafter, the second arm mechanism 20 will be described mainly for the difference from the first arm mechanism 10, and a structure similar to the first arm mechanism 10 will not be described in detail.

The gear mechanism 23 includes a gear box 23a, a first gear 231 housed in the gear box 23a, and a second gear 232 also housed in the gear box 23a and engaged with the first gear 231. It is noted that the rotation axes of the first gear 231 and the second gear 232 are substantially in parallel with the output shaft 4b.

The second slider 42 is connected to the other end of the driven arm 22 through a connection member 44. The other end of the driven arm 22 is connected to the connection member 44 via the bearing 24. The connection member 44, bearing 24 and driven arm 22 are arranged below the first guide rail 31 and the first slider 32 so as not to interfere with the first guide rail 31 and the first slider 32.

In the case where the output shaft 4b rotates about its axis, the driving arm 21 rotates with its one end being the rotation center, and the gear mechanism 23 also rotates with the one end of the driving arm 21 being the rotation center. Since the other end of the driving arm 21 is connected to the first gear 231, the first gear 231 rotates about its axis and the second gear 232 also rotates. The rotation of the second gear 232 makes the driven arm 22 rotate with its other end being the rotation center, and the second slider 42 as well as the second hand holding member 43 that are connected to one end of the driven arm 22 move on the second guide rail 41. The second arm mechanism 20 is elongated and shortened in the horizontal direction.

The second arm mechanism 20 is so configured to be able to move along the length corresponding to at least substantially half the length of the second guide rail 41. The base end of the driving arm 21 is connected to the output shaft 4b, and the output shaft 4b is disposed at a position corresponding to the middle of the second guide rail 41. Accordingly, the second arm mechanism 20 may move between the middle part of the second guide rail 41 and each end of the second guide rail 41. In other words, the second arm mechanism 20 is so configured to be able to move along the entire length of the second guide rail 41.

The transfer apparatus 100 according to the embodiment is capable of carrying out precise transfer as in a vacuum transfer robot of the belt slidable type, without harming the clean environment by dust generation from a belt.

In the case of using a belt, stretch of the belt causes a delay in transmission of power. According to the embodiment, as the driving arms 11, 21 and the driven arms 12, 22 are connected to the first gears 131, 231 and the second gears 132, 232, respectively, power may be transmitted from the drive source 2 to the first slider 32, the first hand holding member 33, the second slider 42 and the second hand holding member 43, without the delay as described above. Moreover, absence of the stretch of a belt suppresses deterioration in the accuracy of positioning.

Furthermore, the first shaft part 131a and the second shaft part 132a protrude in directions opposite from each other, and the driving arm 11 and the driven arm 12 are connected to the first shaft part 131a and the second shaft part 132a. Even if the driving arm 11 and the driven arm 12 rotate, they do not interfere with each other. If the driving arm 11 and the driven arm 12 interfere with each other, the movable range of the first arm mechanism 10 is limited to an area in which they do not interfere with each other. Since the driving arm 11 and the driven arm 12 do not interfere with each other, the movable range of the first arm mechanism 10 is longer compared to the case where they interfere with each other, and the length of the first arm mechanism 10, i.e. the lengths of the driving arm 11 and the driven arm 12, may be made shorter with respect to the movable range of the first arm mechanism 10 in the longitudinal direction of the first guide rail 31. The second arm mechanism 20 may have the effect as described above as well as the first arm mechanism 10.

Moreover, one end (base end) of each of the driving arms 11, 21 is connected to the drive source 2, and is positioned at a middle part in the longitudinal direction of the first guide rail 31 and the second guide rail 41. Since the first arm mechanism 10 and the second arm mechanism 20 are so configured as to move along a length corresponding to at least substantially half the length of the first guide rail 31 and the second guide rail 41, the first arm mechanism 10 and the second arm mechanism 20 may move between both ends of the first guide rail 31 and the second guide rail 41 starting from a point at the middle part of the first guide rail 31 and the second guide rail 41.

Moreover, compared to the conventional transfer robot, the embodiment is advantageous in the following points. Conventionally, a motor is located inside the first arm (corresponding to the driving arms 11, 21). Furthermore, the first arm is provided with a rotary shaft which transmits the rotation of the motor and a passage through which a cable passes. The rotary shaft is located at a connection part of the first arm and the second arm (corresponding to the driven arms 12, 22), and the rotary shaft as well as the passage are provided with vacuum seal members. That is, in order to fabricate the first arm, it is necessary to prepare a metal mold or to perform complicated cutting for realizing a complicated structure in which the motor, rotary shaft, vacuum seal member and the like may be arranged. Furthermore, two vacuum seal members are required for one arm.

According to the embodiment, on the other hand, the driving arms 11, 12 have simplified structures. Thus, the driving arms 11, 21 may be fabricated by simple shaving without using the mold. It is noted that the structure of the driving arms 11, 12 is not limited to the above examples but may also employ a hollow or solid structure, for example.

Furthermore, since the drive source 2 is disposed near the base end of each of the driving arms 11, 21, a vacuum seal member may be provided only at the base end of each of the driving arms 11, 12, so that the number of vacuum seal members for one arm may be reduced. As a result, a transfer apparatus may be manufactured at a cost substantially equal to or lower than the cost for the conventional robot according to Japanese Patent Application Laid-Open Publication No. 2014-78693.

Also in the embodiment, since the drive source 2 is disposed near the base end of each of the driving arms 11, 21, not at the connection part of the driving arms 11, 21 and the driven arms 12, 22, the distance between the motor 3 and the support shaft 50 is shortened, which can reduce the inertia (torque) with respect to the support shaft 50.

Conventionally, a motor is located near the connection part of the first arm and the second arm, which causes the motor to be close to the wall surface of a chamber which houses a substrate processing device, and thus to be easily affected by radiant heat from the wall surface of the chamber. According to the embodiment, as the motor 3 is located near the base end of each of the driving arms 11, 21, the motor 3 is farther from the wall surface of the chamber 61 than that in the conventional technology, and thus is more difficult to be affected by the radiant heat.

While the transfer apparatus 100 as described above comprises the first arm mechanism 10 and the second arm mechanism 20, it may also comprise only one of them. According to the embodiment, the output shafts 4a, 4b of the speed reducer 4 protrude upward, while they may also protrude in the horizontal direction. In such a case, the first arm mechanism 10 and the second arm mechanism 20 are elongated and shortened in the vertical direction, to move the first hand holding member 33 and the second hand holding member 43.

The transfer apparatus 100 may also transfer an object other than a substrate, e.g., a work processed by a machine tool.

It is to be noted that, as used herein and in the appended claims, the singular forms “a”, “an”, and “the” include plural referents unless the context clearly dictates otherwise.

It should be understood that the embodiments disclosed herein are illustrative and non-restrictive in every respect. The technical features described in the examples may be combined with one another, while all changes that fall within metes and bounds of the claims, or equivalence of such metes and bounds thereof are intended to be embraced by the scope of the present invention.

What is claimed is:

1. A transfer apparatus, comprising:
a transfer unit that moves on a rail and transfers an object; and
an arm mechanism that transmits power from a drive source to the transfer unit,
wherein
the arm mechanism includes
a rotatable driving arm with one end connected to the drive source,
a driven arm with one end connected to the transfer unit, and
a gear mechanism that connects another end of the driven arm to another end of the driving arm, and transmits rotation of the driving arm to the driven arm.

2. The transfer apparatus according to claim 1, wherein
the gear mechanism includes
a first gear connected to said another end of the driving arm, and
a second gear engaged with the first gear and connected to said another end of the driven arm.

3. The transfer apparatus according to claim 2,
wherein the first gear includes
a first gear part, and
a first shaft part protruding from the first gear part,
wherein the second gear includes
a second gear part engaged with the first gear, and
a second shaft part protruding from the second gear part in a direction opposite to the first shaft part, and
wherein the driving arm is connected to the first shaft part and the driven arm is connected to the second shaft part.

4. The transfer apparatus according to claim 1, wherein the drive source is located next to a middle part in a longitudinal direction of the rail.
